(19) United States
(12) Patent Application Publication
(10) Pub. No.: US 2026/0060042 A1
(43) Pub. Date: Feb. 26, 2026

(54) SOLDER CONTACT RESISTANCE/RESISTIVITY TESTING STRUCTURE

(71) Applicant: International Business Machines Corporation, Armonk, NY (US)

(72) Inventors: Nikiforos Fokas, Albany, NY (US); Christopher J. Waskiewicz, Rexford, NY (US); FEE LI LIE, Albany, NY (US); Kevin Wayne Brew, Niskayuna, NY (US)

(21) Appl. No.: 18/813,983

(22) Filed: Aug. 23, 2024

(51) Int. Cl. H01L 21/66; G01R 31/28; G01R 31/71; H01L 23/498

(52) U.S. Cl. CPC H01L 22/34; G01R 31/2896; G01R 31/71; H01L 23/49816

(57) ABSTRACT

A heterogeneous integration testing structure is provided that includes a solder bridge that is configured for solder contact resistance measurement or solder sheet resistivity measurement. The heterogeneous integration testing structure is typically integrated in a far back-end of an integrated circuit containing structure. The solder bridge includes under ball metallurgy and solder that is formed over a plurality of electrical components located in the far back-end of the integrated circuit containing structure in which solder contact resistance measurement or solder sheet resistivity measurement is required.

### BACKGROUND

The present application relates to semiconductor technology, and more particularly to a heterogeneous integration testing structure that contains at least one solder bridge that can be used for solder contact resistance measurement or solder sheet resistivity measurement.

The Kelvin Method, also known as Kelvin Probing or 4-wire measurement, is a technique used in circuitry to measure the resistance values of electrical components, especially resistors. This method helps eliminate the impact of transition resistances on the measurement to provide more accurate and reliable results, especially in situations where the resistance being measured is very low. The Kelvin Method is commonly employed in applications where precision resistance measurements and high accuracy are essential. In the Kelvin Method, two leads are used to apply a known current to an electrical component under testing. These leads typically have low resistance. Another set of two leads, separate from the current leads mentioned above, is used to measure the voltage across the electrical component under testing. These leads are connected close to the electrical component under testing where the voltage is being measured. The voltage drop is measured without including the electrical component of the connecting leads, as they are separate from the current-carrying leads. The resistance, R, can be calculated using Ohm's Law: R=V/I, where V is the voltage across the electrical component under test, and I is the current flowing through it.

### SUMMARY

A heterogeneous integration testing structure is provided that includes a solder bridge that is configured for solder contact resistance measurement or solder sheet resistivity measurement. The heterogeneous integration testing structure is typically integrated in a far back-end of an integrated circuit containing structure. The solder bridge includes under ball metallurgy (UBM) and solder that is formed over a plurality of electrical components located in the far back-end of the integrated circuit containing structure in which solder contact resistance measurement or solder sheet resistivity measurement is required.

In one embodiment of the present application, a structure is provided that includes an integrated circuit containing structure including a far back-end having a plurality of electrical components located in a test area, and a solder bridge in electrical contact with each electrical component of the plurality of electrical components present in the test area, in which the solder bridge is configured to measure solder contact resistance of at least one of the electrical components of the plurality of electrical components present in the test area.

In another embodiment of the present application, a structure is provided that includes an integrated circuit containing structure including a far back-end having a plurality of electrical components located in a test area, and a solder bridge in electrical contact with each electrical component of the plurality of electrical components present in the test area, wherein the solder bridge is configured to measure solder sheet resistivity of the electrical components of the plurality of electrical components present in the test area.

In a further embodiment of the present application, a structure is provided that includes an integrated circuit containing structure including a far back-end having a plurality of electrical components located in a test area and an elongated shaped solder bridge in electrical contact with each electrical component of the plurality of electrical components present in the test area, wherein the elongated shaped solder bridge is configured to measure solder contact resistance of at least one of the electrical components of the plurality of electrical components present in the test area.

### BRIEF DESCRIPTION OF THE DRAWINGS

FIG. 1A illustrates a design layout of a heterogeneous integration test structure that can be used to measure solder contact resistance in a test area in accordance with an embodiment of the present application.

FIG. 1B is a cross sectional view of one of the electrical components in the test area of the heterogeneous integration test structure illustrated in FIG. 1A.

FIG. 1C is a cross sectional view of the test area including the solder bridge that is present in the heterogeneous integration test structure of FIG. 1A.

FIG. 2 illustrates a design layout of another heterogeneous integration test structure that can be used to measure solder contact resistance in a test area in accordance with an embodiment of the present application.

FIG. 3 illustrates a design layout of yet another heterogeneous integration test structure of the present application that can be used to measure solder contact resistance in an array of solder bumps.

FIG. 4A illustrates a design layout of a further heterogeneous integration test structure of the present application that can be used to measure solder contact resistance in an array of solder bumps.

FIG. 4B illustrates a design layout of a yet further heterogeneous integration test structure of the present application that can be used to measure solder contact resistance in an array of solder bumps.

FIG. 5 illustrates a design layout of a heterogeneous integration test structure that can be used to measure solder contact resistivity in accordance with an embodiment of the present application.

FIG. 6A illustrates a design layout of another heterogeneous integration test structure that can be used to measure solder contact resistivity in accordance with an embodiment of the present application.

FIG. 6B illustrates a design layout of yet another heterogeneous integration test structure that can be used to measure solder contact resistivity in accordance with an embodiment of the present application.

FIG. 7A illustrates a design layout of a still further heterogeneous integration test structure containing elongated shaped solder bridges that can be used to measure solder contact resistance in accordance with an embodiment of the present application.

FIG. 7B illustrates a design layout of an even further heterogeneous integration test structure containing elongated shaped solder bridges that can be used to measure solder contact resistance in accordance with an embodiment of the present application.

FIGS. 8A-8I are cross sectional views illustrating a process that can be used in forming a heterogeneous integration test structure in a far back-end of an integrated circuit structure in accordance with the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Current contact resistance testing methodology requires two probes (or pins) to be landed on a single solder bump. As the solder bump size and pitch scales down, the two pin methodology because increasingly difficult to accomplish. Furthermore, prior contact resistance testing structures require an extra chip and/or a carrier wafer to accomplish contact resistance testing which can increase the size of the testing structure and increase the cost of manufacturing the same. There is a need for providing a solder contact resistance testing structure that avoids/circumvents the drawbacks mentioned above with respect to current solder contact resistance testing structures. Notably, a solder contact resistance testing structure is needed that enables small pitch (less than 55 micron) solder contract resistance testing for future C4 (controlled collapse chip connection) technologic developments. Furthermore, a solder contact resistance testing structure is needed that can be readily integrated in a far back-end of an integrated circuit containing structure or other like structure that uses solder to connect the structure to an external structure. The design of the solder contact resistance testing structure should be such that it can be implemented in production wafers (in, for example, the kerf area) and can be used to monitor wafer health.

The present application provides a heterogeneous integration testing structure that includes a solder bridge. The solder bridge, which includes UBM and overlying solder, can be used for solder contact resistance measurement or solder sheet resistivity measurement on one or more electrical components of an integrated circuit containing structure. The use of a solder bridge to enable measurement of contact resistance/sheet resistivity and determination of solder contact resistivity has not been done before since it may violate design rules in such integrated circuit containing structures. Also, current solder bump structures are large enough to directly probe. However, in the current scaled down regimes of solder for 3D heterogenous chip stacking, bump pitch and size is such that direct contact is difficult.

The heterogeneous integration testing structure of the present application does not include manual probes or use of an extra chip, a carrier wafer or bonded dies. The exclusion of manual probes, an extra chip, a chip carrier wafer and bonded dies from the heterogeneous integration testing structure of the present application allows for faster testing, yield verification, and design iteration without increased cost in manufacturing the integrated circuit containing structure. In some embodiments, the heterogeneous integration testing structure of the present application uses the Kelvin method mentioned above for measuring the contact resistance between solder and underlying electrical components of the integrated circuit containing structure. Sheet resistivity measurement of the solder can be obtained utilizing a transfer line method or transmission line method that has been modified to include the solder bridge of the present application. These and other aspects and advantages of the heterogeneous integration testing structure of the present application will become more apparent from the drawings that accompany the present application as well as with the discussion that follows.

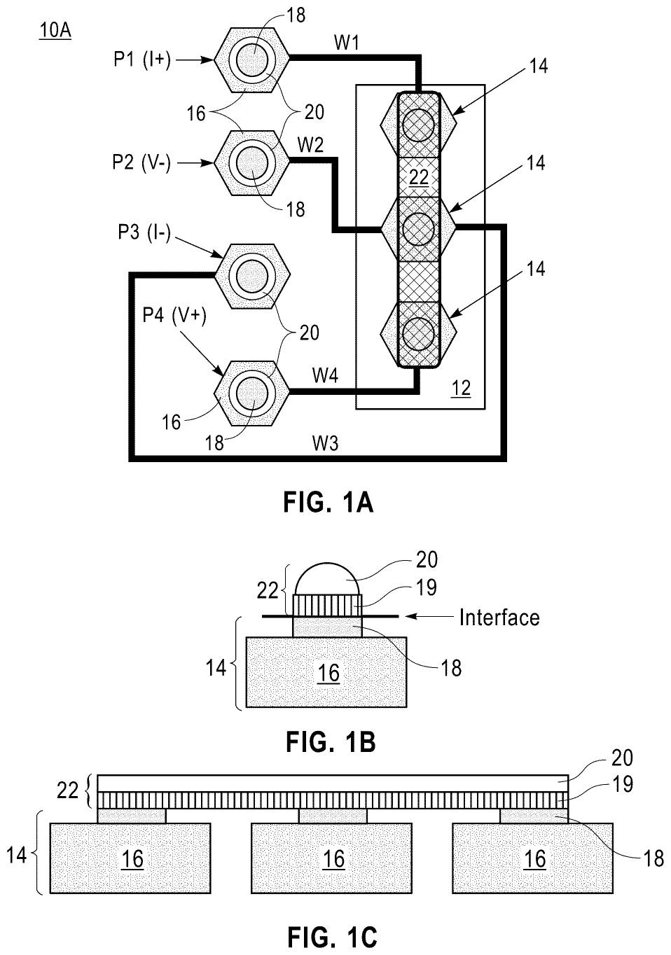

Referring first to FIG. 1A, there is illustrated a design layout of a heterogeneous integration test structure 10A that can be used to measure solder contact resistance in accordance with an embodiment of the present application. The heterogeneous integration test structure 10A illustrated in FIG. 1A is integrated in a far back-end of an integrated circuit containing structure and is configured to measure contact resistance between the solder and at least one underlying electrical component that is located in the far back-end of the integrated circuit containing structure. Notably, the contact resistance is measured in a test area 12 and at an interface between solder bridge 22 and one or more electrical components 14 (which can include, for example, underlying metal wiring 16 and a terminal metal pad containing structure 18) that is located at a far back-end of an integrated circuit containing structure. The heterogeneous integration test structure 10A illustrated FIG. 1A can include four probes, namely first probe P1, second probe P2, third probe P3 and fourth probe P4. In this embodiment, the four probes are collinear probes in which two of the probes, i.e., P1 and P3, are used for sourcing current, and the other two probes, i.e., P2 and P4, as used for measuring voltage drop in the test area 12. In some embodiments of the present application and as is illustrated in FIG. 1A, P1 sources a high current (I+), while P4 sources a low current (I−). In the present application, P2 measures low voltage drop (V−), while P4 measures a high voltage drop (V+). Other configurations for V and I are possible; this holds true for the other drawings in which V and I are labeled.

In embodiments of the present application, P1 is wired to one of electrical components 14 in test area 12 by first wire W1, P2 is wired to another of electrical components 14 in test area 12 by second wire W2, and P4 is wired to a yet another of the electrical components 14 in test area 12 by fourth wire W4. In the illustrated embodiment of FIG. 1A, P3 is wired to the same electrical component 14 as P2 by a third wire W3.

In the embodiment illustrated in FIG. 1A, each of the four probes, P1, P2, P3 and P4 includes underlying metal wiring 16, a terminal metal pad containing structure 18 and solder bump structure 22. Although not illustrated in FIG. 1A, under ball metallurgy (UBM) is typically located between the terminal metal pad containing structure 18 and solder 20 that provides each of the four probes. Metal wiring 16 can also be referred to as underlying interconnect wires. The metal wiring 16 and the terminal metal pad containing structure 18 are composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy. The terminal metal pad containing structure 18 includes a terminal level via and a metal pad. The terminal level via and metal bad can be composed of a compositionally same, or different, electrically conductive metal or electrically conductive metal alloy. In one example, Al is in providing both the terminal level via and the metal pad that provide the terminal metal pad containing structure 18. The UBM can include a Ni bond pad that is stacked over a Cu bond pad. Other types of UBMs that can be used in the present application include, but are not limited to, a stack of Cu/Ni/Cu. Solder 22 includes any type of solder that is used in the semiconductor industry including, for example, lead containing solder and lead free solder. In one example, the solder 22 is composed of tin-silver alloy. The metal wiring 16 can have various shapes include rectangular or polygonal as is the case illustrated in FIG. 1A.

The test area 12 includes solder bridge 22 and a plurality of underlying electrical components 14 (three of which are shown in FIG. 1A) in which solder contact resistance measurement on at least one of the electrical components will be subsequently performed. Solder bridge 22 incudes UBM and an overlying continuous layer of solder. The continuous layer of solder and UBM that provide the solder bridge 22 are not separately illustrated in FIG. 1A, but meant to be included in the area defined as the solder bridge 22. The solder that provides the continuous layer of the solder bridge 22 includes, for example, lead containing solder or lead free solder (e.g., a tin-silver alloy), and the UBM used in the solder bridge 22 is the same as described above for the probes. Solder bridge 22 extends over, and between, each of the electrical components 14 that are present in the test area 12; this is better illustrated in FIG. 1C. In the illustrated embodiment, each of the plurality of electrical components 14 within the test area 12 includes metal wiring 16 and a terminal metal pad containing structure 18, as defined above. FIG. 1B shows a portion of solder bridge 22 shown in FIG. 1A. In this drawing, UBM 19 of the solder bridge 22 is shown beneath the solder 20. The contact resistance is measured at the interface between the solder bridge 22 and the terminal metal pad containing structure 18 of at least one of the electrical components 14 in test area 12. FIG. 1C shows a cross sectional view of the test area 12 shown in FIG. 1A including solder bridge 22 (including UBM 19 and solder 20) and electrical components 14. Note that the electrical components 14 in the test area 12 as well as any outside the test area (including P1, P2, P3 and P4) are congruent to the same level and can be equally spaced apart (i.e., symmetrically spaced) or they can be unequally spaced apart (i.e., asymmetrically spaced). Solder contact measurement can be performed in either scenario. Solder bridge 22 can have various shapes including, but not limited to a rectangular prism.

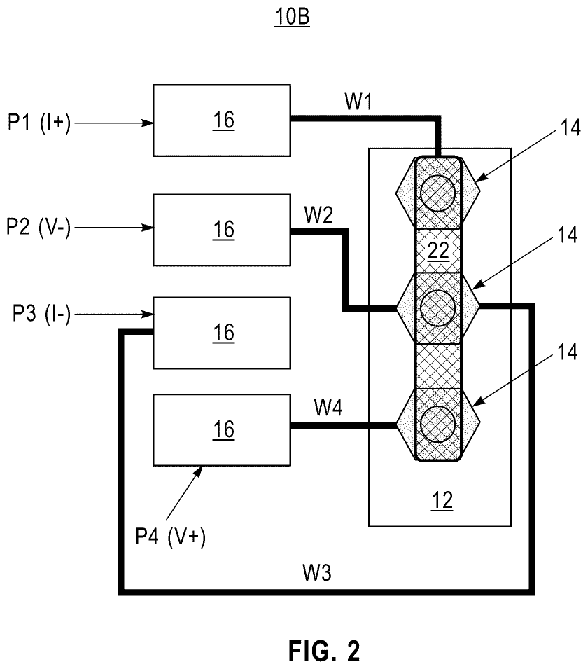

Referring now to FIG. 2, there is illustrated a design layout of another heterogeneous integration test structure 10B that can be used to measure solder contact resistance in accordance with another embodiment of the present application. Heterogeneous integration test structure 10B is similar to the heterogeneous integration test structure 10A illustrated in FIG. 1A except that each of P1, P2, P3 and P4 only includes metal wiring 16 (no terminal metal pad containing structure 18 or UBM/solder is present in providing each of P1, P2, P3 and P4). In this embodiment, the metal wiring 16 that provides each of P1, P2, P3 and P4 can be from an electronic connection that is not congruent to the level of the test area 12 (e.g., from a bonded chiplet with connections removed from the UBM level) as compared to the metal wiring 16 (e.g., congruent level metal) of each of the electrical components 14 in the test area 12. The electrical components 14 in the test area 12 of FIG. 2 as well as any outside the test area (including P1, P2 P3 and P4) can be equally spaced apart (i.e., symmetrically spaced) or they can be unequally spaced apart (i.e., asymmetrically spaced). Solder contact measurement can be performed in either scenario.

It is noted that the heterogeneous integration test structure 10A illustrated in FIG. 1A and the heterogeneous integration test structure 10B illustrated in FIG. 2 can measure contact resistance for scaled electrical components 14 that are within the test area 12, without changing the size of each of P1, P2, P3 and P4.

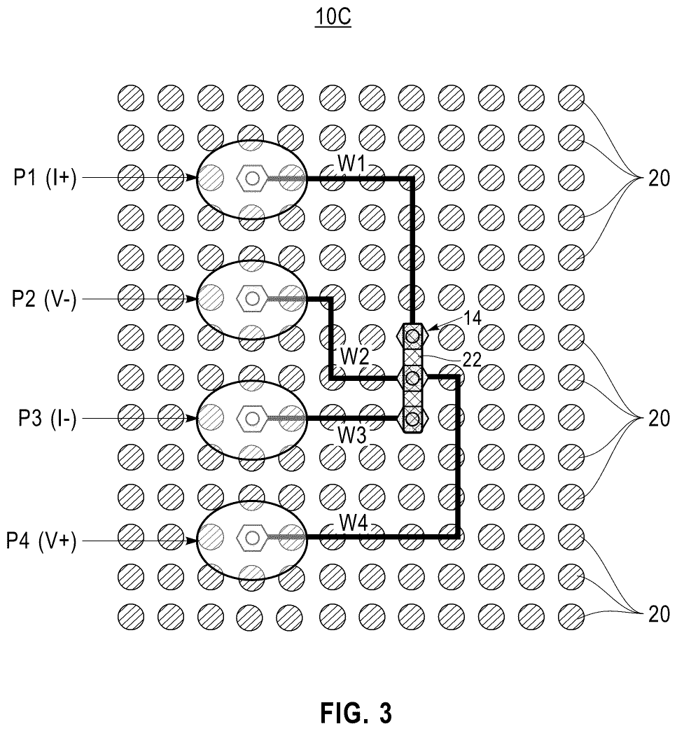

Referring now to FIG. 3, there is illustrated a design layout of yet another heterogeneous integration test structure 10C of the present application that can be used to measure solder contact resistance in an array of solder bumps 20. In this embodiment, P1, P2, P3 and P4 are large probes that contact multiple solder bumps 20. In the illustrated embodiment, the multiple solder bumps 20 are symmetrically spaced apart from each other and the electrical components 14 in the test area 12 are also symmetrically spaced apart from each other. Other spacing configuration are possible and can be used in the heterogeneous integration test structure 10C In the some embodiments, the metal wiring 16 of the electrical components 14 present in heterogeneous integration test structure 10C can be an exposed metal level where direct probing can occur.

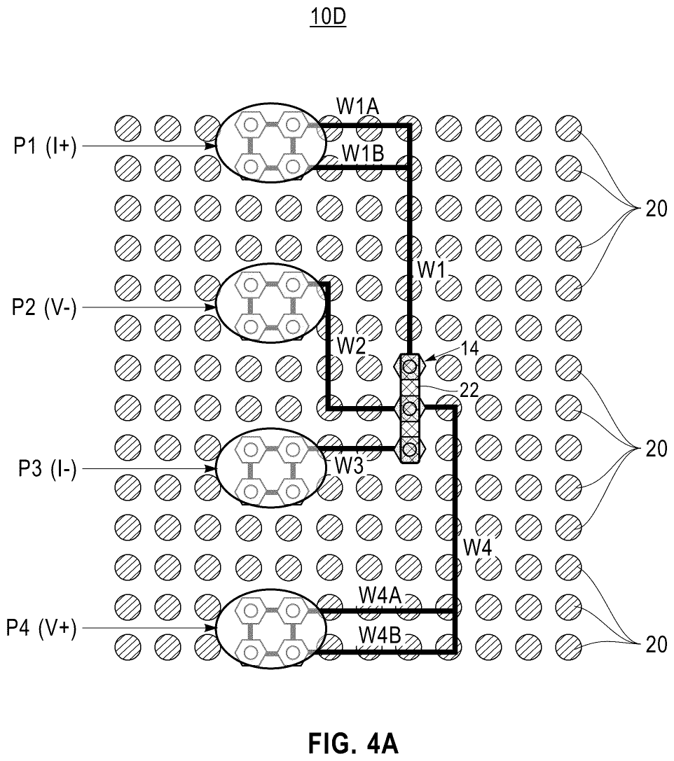

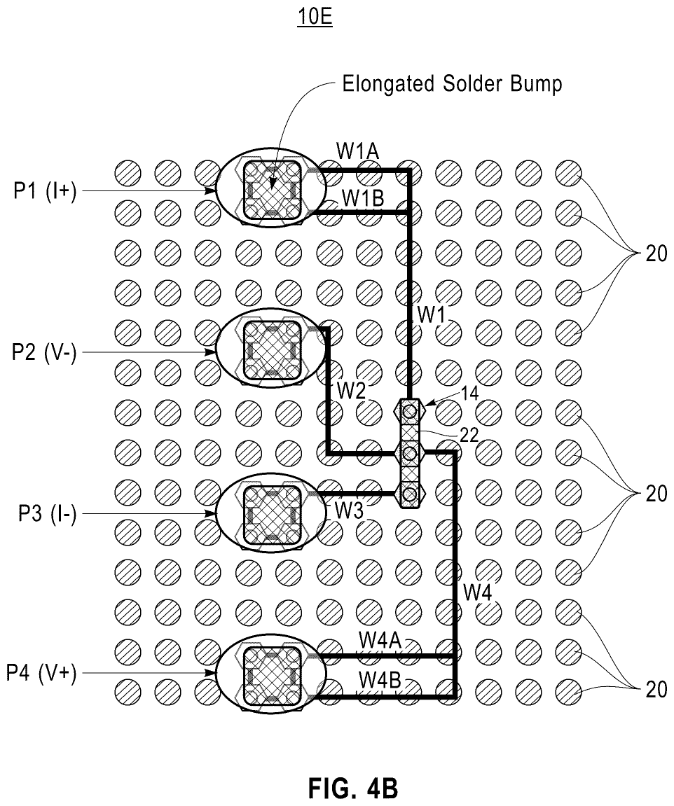

Referring now to FIG. 4A, there is illustrated a design layout of a further heterogeneous integration test structure 10D of the present application that can be used to measure solder contact resistance in an array of solder bumps 20. In this embodiment, P1, P2, P3 and P4 are large probes that contact multiple solder bumps 20 that are shorted at the metal wiring level. In FIG. 4A, wires W1A and W1B from P1 merged into W1, and wires W4A, W4B merge into W4. Similar merging occurs with respect to W2 and W3. In the illustrated embodiment, the multiple solder bumps 20 are symmetrically spaced apart from each other and the electrically components 14 in the test area are also symmetrically spaced apart from each other. Other spacing configuration are possible and can be used in the heterogeneous integration test structure 10D.

Referring now to FIG. 4B, there is illustrated another design layout of a yet further heterogeneous integration test structure 10E of the present application that can be used to measure solder contact resistance in an array of solder bumps 20. The design layout shown in FIG. 4B is similar to the design layout shown in FIG. 4A except that elongated solder bumps extending in one or more dimensions is also used to increase the contact area for the probes. In the illustrated embodiment, the multiple solder bumps 20 are symmetrically spaced apart from each other and the electrically components 14 in the test area are also symmetrically spaced apart from each other. Other spacing configuration are possible and can be used in the heterogeneous integration test structure 10E.

Notably, a structure is provided in each of FIGS. 1A, 1B, 1C, 2, 3, 4A, and 4B that includes an integrated circuit containing structure including a far back-end having a plurality of electrical components 14 located in test area 12. A solder bridge 22 is present and, the solder bridge 22 is in electrical contact with each electrical component 14 of the plurality of electrical components present in the test area 12. The solder bridge 22 is configured to measure solder contact resistance of at least one of the electrical components 14 of the plurality of electrical components present in the test area 12. The configuration includes P1, P2, P3 and P4 and W1, W2, W3 and W4 as mentioned above.

In some embodiments (see, for example, FIGS. 1A, 2, 3, 4A, and 4B), each of the electrical components 14 in the test area 12 is symmetrically spaced apart from each other.

In some embodiments, each of the electrical components 14 in the test area 12 is asymmetrically spaced apart from each other.

In embodiments of the present application (See, for example, FIGS. 1B and 1C), the solder bridge 22 includes under ball metallurgy 19 located beneath a continuous layer of solder 20.

In some embodiments, the under ball metallurgy 19 of the solder bridge 22 includes a first under ball metal layer composed of a first under ball metal and a second under ball layer composed of a second under ball metal, in which the second under ball metal is compositionally different from the first under ball metal.

In some embodiments of the present application (See, for example, FIGS. 1A, 1B, 1C, 2, 3, 4A, and 4B), the electrical components 14 in the test area 10 include metal wiring 16 and a terminal metal pad containing structure 18. As previously mentioned, the terminal metal pad containing structure 18 includes a terminal metal pad structure and a metal pad.

In embodiments of the present application (See, for example, FIGS. 1A, 2, 3, 4A and 4B), first probe P1, second probe P2, third probe P3 and fourth probe P4 are electrically wired (see, W1, W2, W3 and W4 in FIGS. 1-4) to the electrical components 14 of the plurality of electrical components present in the test area 12.

In some embodiments (See, for example, FIG. 2), each of the first probe, the second probe, the third probe and the fourth probe includes metal wiring 16.

In some embodiments (See, for example, FIGS. 1A, 1B and 1C), each of the first probe, the second probe, the third probe and the fourth probe includes metal wiring 16, terminal metal pad containing structure 18, under ball metal 19, and solder 20.

In some embodiments (See, for example, FIGS. 3A, 3B, 4A and 4B), each of the first probe, the second probe, the third probe and the fourth probe contact a plurality of solder bumps 20.

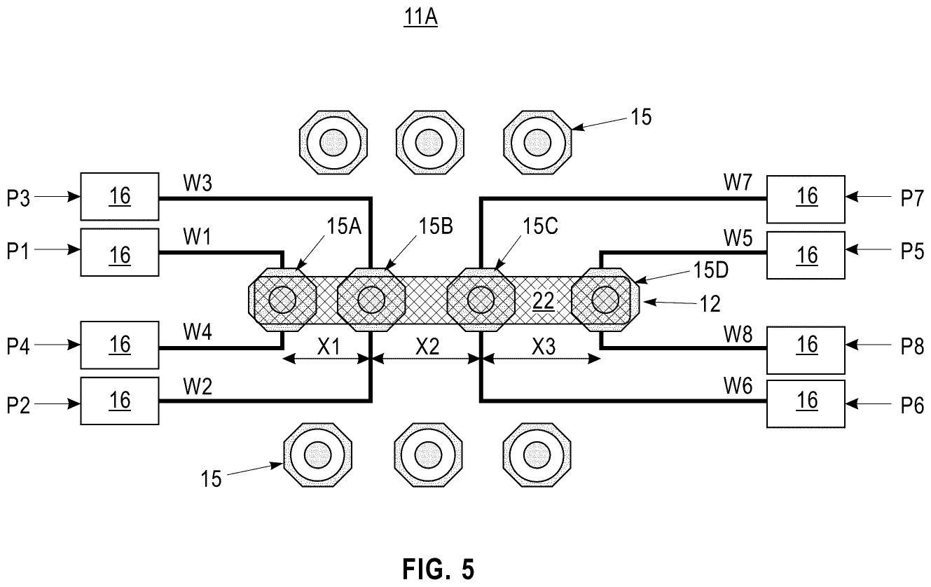

Referring now to FIG. 5, there is illustrated a design layout of a heterogeneous integration test structure 11A that can be used to measure solder contact resistivity (i.e., sheet resistivity) in accordance with an embodiment of the present application. Notably, the heterogeneous integration test structure 11A is a modified TLM structure that includes P1, P2, P3, P4, P5, P6, P7 and P8. The eight probes include metal wiring 16. The metal wiring 16 that provides each of the eight probes can be metal connections of various shapes and positions (e.g., non-congruent to the UBM level) as shown in FIG. 5. The heterogeneous integration test structure 11A also includes solder bridge 22 which extends over electrical components, e.g., a first electrical component 15A, a second electrical component 15B, a third electrical component 15C and a fourth electrical component 15D, that are present in test area 12. As is shown, P1 is wired through W1 to the first electrical component 15A within the test area 12 and P4 is wired through W4 to the first electrical component 15A within the test area 12. As is further shown, P3 is wired through W3 to the second electrical component 15B within the test area 12 and P2 is wired through W2 to the second electrical component 15B within the test area 12. As is shown, P6 is wired through W6 to the third electrical component 15C and P7 is wired through W7 to the third electrical component 15A within the test area 12. As is shown, P6 is wired through W6 to the third electrical component 15C and P7 is wired through W7 to the third electrical component 15A within the test area 12. As is further shown, P5 is wired through W5 to the fourth electrical component 15D and P8 is wired through W8 to the fourth electrical component 15D within the test area 12.

As is illustrated in FIG. 5, the first electrical component 15A is spaced apart from the second electrical component 15B by a first contact separation distance X1, the second electrical component 15B is spaced apart from the third electrical component 15C by a second contact separation distance X2, and third electrical component 15C is spaced apart from the four electrical component 15D by a fourth contact separation distance X4. In embodiments, X1 is different from X3.

In FIG. 5, electrical components 15 are shown outside of the test area 12. Each electrical component 15 is a conventional UBM structure (i.e., solder and UBM), a terminal metal pad containing structure 18 and metal wiring 16. Each of first electrical component 15A, second electrical component 15C, third electrical component 15C and four electrical component 15D includes a terminal metal pad containing structure 18 and metal wiring 16. In the embodiment illustrated in FIG. 5, the eight pads would measure front contact resistance on 3 gaps (X1, X2, and X3) but can be expanded to a longer solder bump and more contacts. Notably, and in one exemplary embodiment and for X1, by forcing current up though second electrical component 15B to the solder of the solder bridge 22, across to the first electrical component 15A and back down through the first electrical component 15A with increasing current travel length, one can extract 2*contact resistant (RC) precisely. Using the approximation that each of the electrical components 15 outside the test area 12 is negligible, the contact resistivity (Rho-C) can be calculated of the test model contact to the electrical components 15A and 15B with known contact dimension from top down SEM measurement. A slope of a graph of resistance vs contact separation distance, X1, can be used to provide the contact sheet resistance within the test area 12.

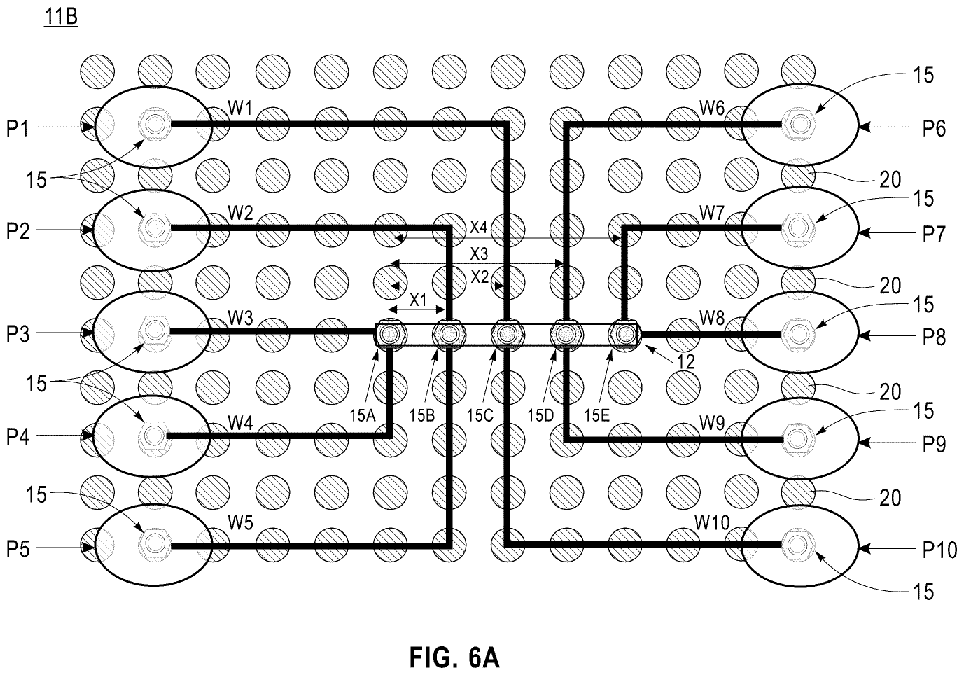

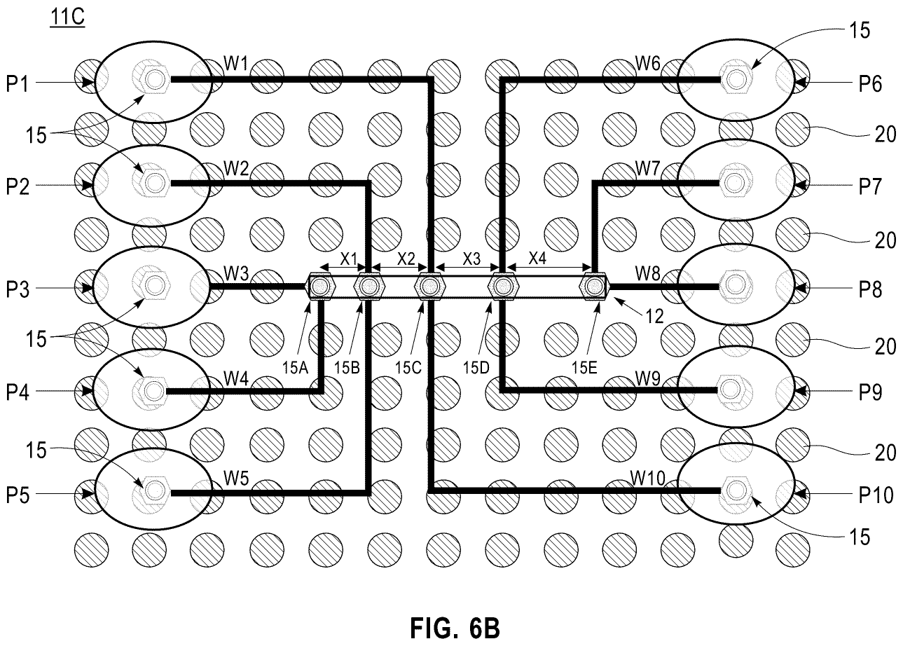

Referring now to FIG. 6A, there is illustrated a design layout of another heterogeneous integration test structure 11B that can be used to measure solder contact resistivity in accordance with an embodiment of the present application. The heterogeneous integration test structure 11B of FIG. 6A is similar to the heterogeneous integration test structure 11A of FIG. 5 except that ten probes P1, P2, P3, P4, P5, P6, P7, P8, P9 and P10 are used instead of 8 probes as shown in FIG. 5 and metal wiring 16 used for each of the probes in the embodiment illustrated in FIG. 5 have been replaced in the embodiment illustrated in FIG. 6A by electrical components 15 defined above. Also and in the embodiment illustrated in FIG. 6A, the test area 12 includes five electrical components, namely first electrical component 15A, second electrical component 15C, third electrical component 15C, four electrical component 15D and fifth electrical component 15E. In another heterogeneous integration test structure 11B, the first electrical component 15A is spaced apart from the second electrical component 15B by a first contact separation distance X1, the first electrical component 15A is spaced apart from the third electrical component 15C by a second contact separation distance X2, the first electrical component 15A is spaced apart from the four electrical component 15D by a fourth contact separation distance X4, and the first electrical component 15A is spaced apart from the fifth electrical component 15E by a fifth contact separation distance X5. In embodiments, X1<, X2<X3<X4<X5. Each of the electrical components in the test area 12 includes a terminal metal pad containing structure 18 and metal wiring 16. In the embodiment illustrated in FIG. 6A, the ten probes would measure front contact resistance on 4 gaps (X1, X2, X3 and X4) but can be expanded to a longer solder bump and more contacts. The front contact resistance for each gap can be measured as described above.

Referring now to FIG. 6B, there is illustrated a design layout of another heterogeneous integration test structure 11C that can be used to measure solder contact resistivity in accordance with yet another embodiment of the present application. The heterogeneous integration test structure 11B of FIG. 6B is similar to the heterogeneous integration test structure 11B of FIG. 6A except the contacts are spaced out differently at the top layer to get resistance versus separation length.

Notably, a structure is provided in FIGS. 5, 6A and 6B that includes an integrated circuit containing structure including a far back-end having a plurality of electrical components (e.g., 15A, 15B, 15C, 15D, etc.) located in test area 12. Solder bridge 22 is present and, the solder bridge 22 is in electrical contact with each electrical component (e.g., 15A, 15B, 15C, 15D, etc.) of the plurality of electrical components present in the test area 12. The solder bridge 22 is configured to measure solder sheet resistivity of the electrical components of the plurality of electrical components (e.g., 15A, 15B, 15C, 15D, etc.) present in the test area. 10.

In embodiments, the solder bridge 22 of FIGS. 5, 6A and 6B includes under ball metallurgy located beneath a continuous layer of solder.

In some embodiments, the under ball metallurgy of the solder bridge 22 illustrated in FIGS. 5, 6A and 6B includes a first under ball metal layer composed of a first under ball metal and a second under ball layer composed of a second under ball metal, wherein the second under ball metal is compositionally different from the first under ball metal.

In embodiments of the present application, each of the electrical components (e.g., 15A, 15B, 15C, 15D and 15E) in the test area 12 includes metal wiring 16.

In embodiments and as shown in FIGS. 5, 5A and 6B, the structure further includes a plurality of probes, (e.g. first probe P1, second probe P2, third probe P3, fourth probe P4, etc.) electrically wired (via W1, W2, W3, W4, etc.) to the electrical components (e.g., 15A, 15B, 15C, 15D, etc,) of the plurality of electrical components present in the test area 12.

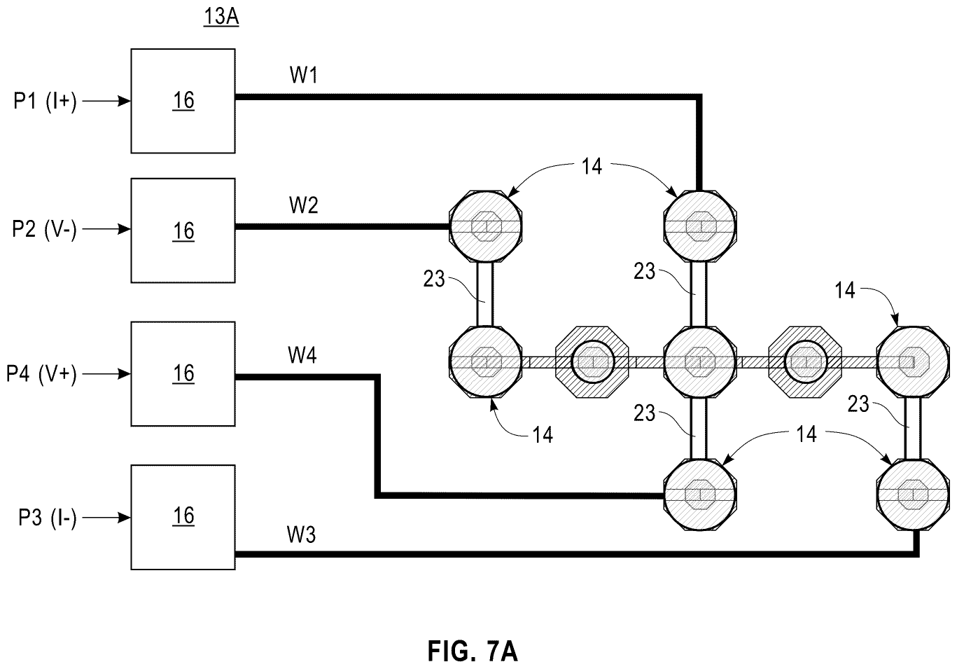

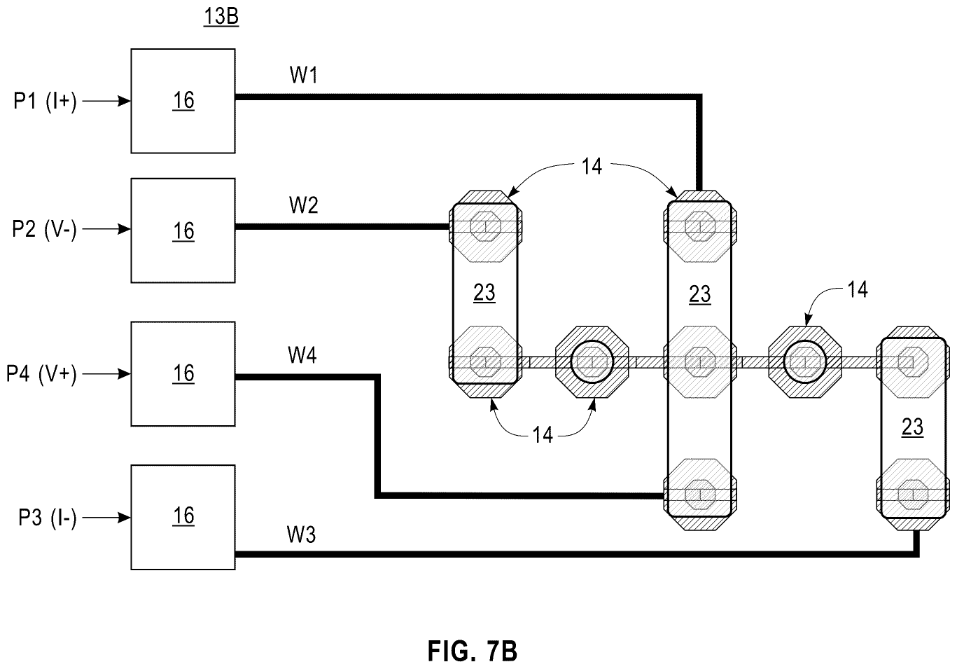

Referring now to FIGS. 7A-7B, there are illustrated design layouts of heterogeneous integration test structure 13A and 13B, respectively. Each of heterogeneous integration test structure 13A and 13B contains elongated shaped solder bridges 23 that can be used to measure solder contact resistance in accordance with an embodiment of the present application. The elongated shaped solder bridges 23 provide electrical connection between electrical components 14. Electrical components 14 include metal wiring 16, terminal metal pad containing structure 18, UBM and solder. The elongated shaped solder bridges 23 includes UBM located beneath a continuous layer of solder. In this exemplary structure, the heterogeneous integration test structure 13 includes P1, P2, P3 and P4 in the form of metal wires 16. The metal wiring 16 can have various shapes including rectangular as shown in FIGS. 7A-7B. As is shown, P1 is wired through W1 to a first combination of electrical components 14 electrically connected by elongated shaped solder bridges 23, P4 is wired through W4 to the first combination of electrical components 14 electrically connected by elongated shaped solder bridges 23. As is further shown, P3 is wired through W3 to a second component of electrical components 14 and P2 is wired through W2 to the second combination of electrical components 14.

Notably, a structure is provided in FIGS. 7A-7B that includes an integrated circuit containing structure including a far back-end having a plurality of electrical components 14 located in test area 10 and an elongated shaped solder bridge 23 in electrical contact with each electrical component 14 of the plurality of electrical components present in the test area 10. The elongated shaped solder bridge 23 is configured to measure solder contact resistance of at least one of the electrical components 14 of the plurality of electrical components present in the test area.

In some embodiments (See, FIGS. 7A-7B), each of the electrical components 14 in the test area 12 is symmetrically spaced apart from each other.

In some embodiments (not shown but discernible from FIGS. 7A-7B), the electrical components 14 in the test area 12 are asymmetrically spaced apart from each other.

In embodiments, the elongated shaped solder bridge 23 includes under ball metallurgy located beneath a continuous layer of solder.

In embodiments, the structure shown in FIG. 7 further includes first probe P1, second probe P2, third probe P3 and fourth probe P4 electrically wired (via W1, W2, W3 and W4) to the electrical components 14 of the plurality of electrical components present in the test area 12.

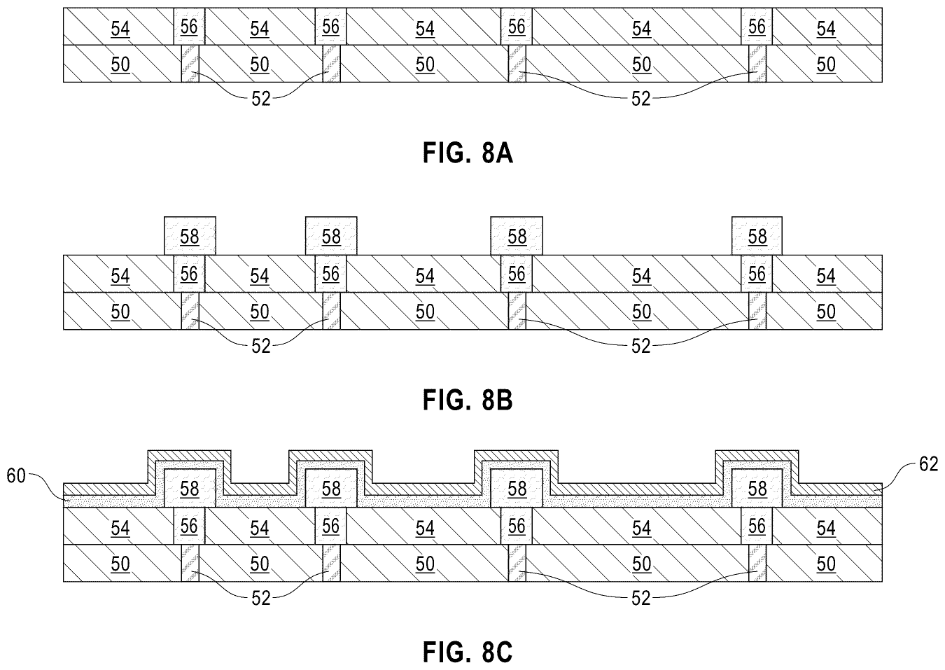

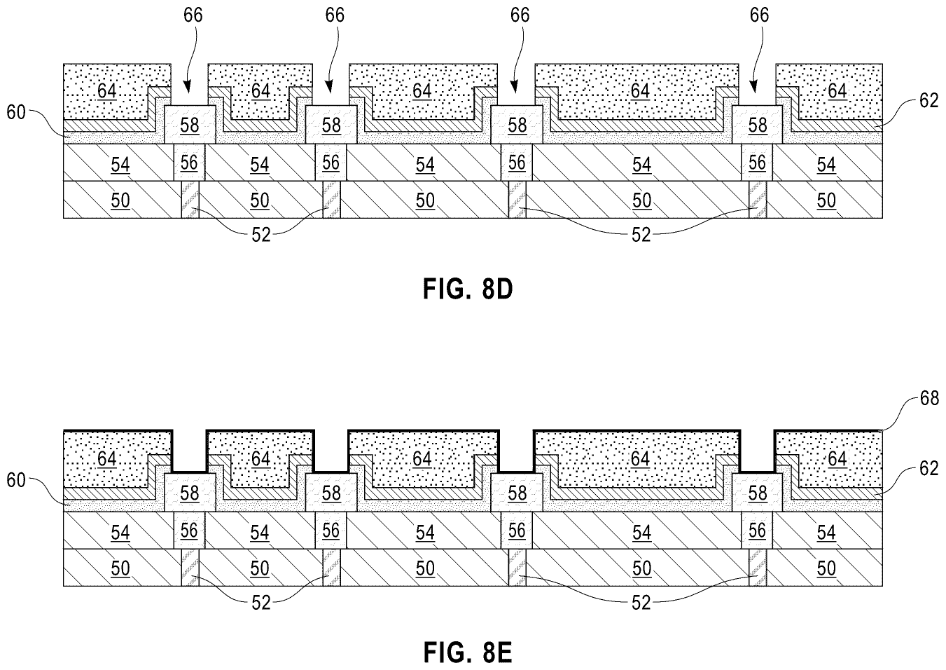

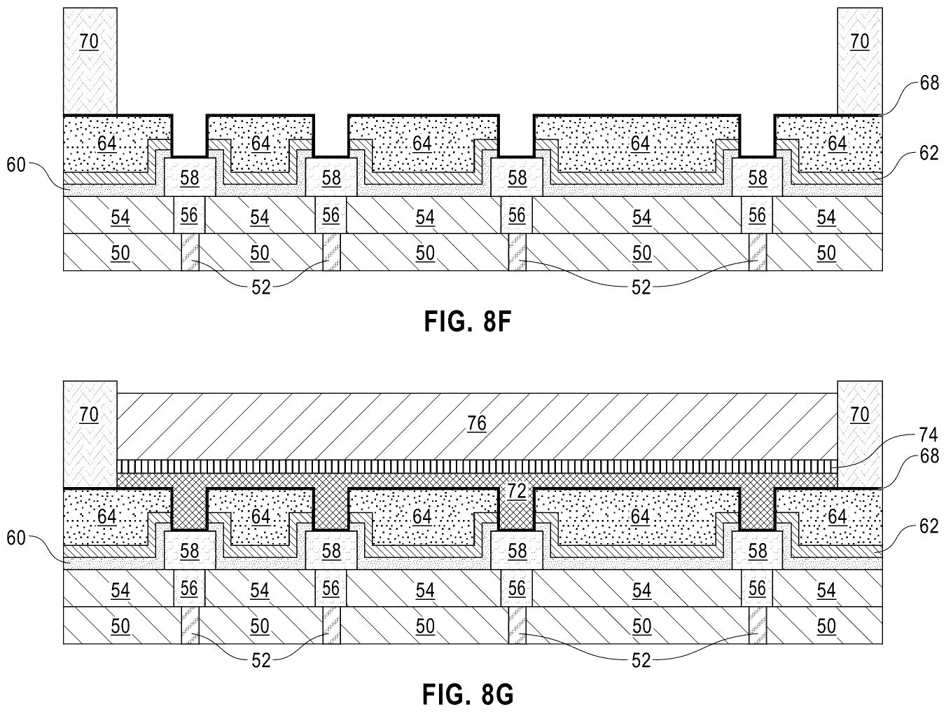

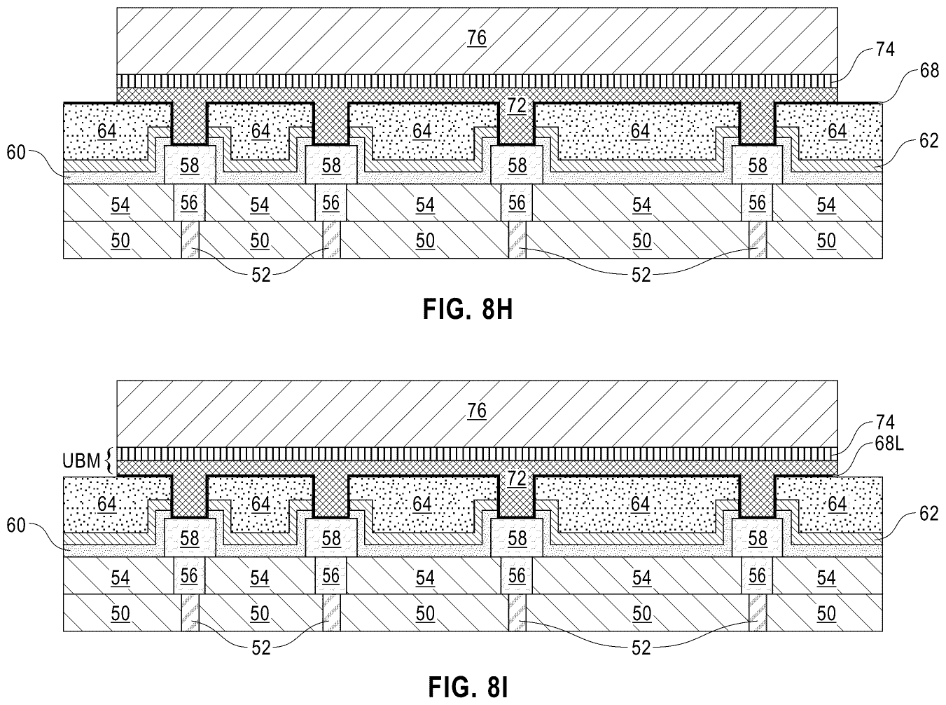

Referring now to FIGS. 8A-8I, there are illustrated a process that can be used in forming a heterogeneous integration test structure to a far back-end of an integrated circuit structure in accordance with the present application. Referring first to FIG. 8A, there is illustrated an exemplary far back-end of an integrated circuit structure that can be employed in the present application. Notably, the exemplary far back-end of the integrated circuit structure illustrated in FIG. 8A includes an nth interconnect level having a plurality of electrically conductive structures 52 embedded in a first interlayer dielectric (ILD) layer 50, and a nth+1 interconnect level having a plurality of terminal metal pad structures 56 embedded in a second ILD layer 54. Other interconnect levels can be present beneath the nth interconnect level and a front-end-of-the-line (FEOL) can be located beneath the lowest interconnect level (collectively each of the interconnect levels provide a back-end-of-the-line (BEOL) interconnect structure in which the nth and nth+1 levels represent the far back-end of the far back-end of the integrated circuit structure.

The first ILD layer 50 is composed of a ILD material including, but not limited to, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. All dielectric constants mentioned herein are measured in a vacuum unless otherwise noted. The electrically conductive structures 52 are metal wires (corresponding to metal wires 16 mentioned above) that are composed of an electrically conductive metal or an electrically conductive metal alloy both as defined above.

The nth interconnect level can be formed by a damascene process which includes forming the first ILD layer 50 by deposition of the ILD material, followed by a planarization process (such as, for example, chemical mechanical polishing (CMP)). Next, openings are formed into the first ILD layer 50 utilizing photolithography and etching. An electrically conductive metal or electrically conductive metal alloy is then depositing into the openings and on a topmost surface of the first ILD layer 50. A planarization process can then be used to remove the electrically conductive metal or electrically conductive metal alloy that is formed on the topmost surface of the first ILD layer 50, while leaving electrically conductive metal or electrically conductive metal alloy inside each of the openings. The maintained electrically conductive metal or electrically conductive metal alloy that is present in the openings provide the electrically conductive structures 52. Alternatively, a subtractive etching process can be used in which a layer of the electrically conductive metal or electrically conductive metal alloy is formed and then photolithography and etching can be used to pattern the layer of electrically conductive metal or electrically conductive metal alloy into electrically conductive structures 52. After forming the electrically conductive structures 52, the first ILD layer 50 by deposition of the ILD material, followed by a planarization process.

The second ILD layer 54 is composed of an ILD material including those mentioned above for the first ILD layer 50. The second ILD layer 54 can be compositionally the same as, or compositionally different from, the first ILD layer 50. The terminal metal pad structures 56 can composed of an electrically conductive metal or an electrically conductive metal alloy both as defined above. The terminal metal pad structures 56 can be composed of a compositionally same, or a compositionally different, electrically conductive metal or electrically metal alloy as the electrically conductive structures 52. In one example, each terminal metal pad structure 56 is composed of Al, while each electrically conductive structure 52 is composed of Cu. The nth+1 interconnect level can be formed by a damascene process or a substrative etch process both as described above in regard to the forming the nth interconnect level.

Referring now to FIG. 8B, there is illustrated the exemplary structure of FIG. 8A after forming metal pads 58 on the n+1 interconnect level, in which each metal pad 58 is in electrical contact with an underlying terminal metal pad structure 56. In the present application, the metal pad 58 and the terminal metal pad structure 56 form terminal metal pad containing structure 18 mentioned above. The metal pads 58 are composed of an electrically conductive metal or an electrically conductive metal alloy both as defined above. The metal pads 58 can be composed of a compositionally same, or a compositionally different, electrically conductive metal or electrically metal alloy as the terminal metal pad structures 56. In one example, Al is used in providing the metal pads 58 and the terminal metal pad structures 56. The metal pads 58 are formed by a substrative etching process as mentioned above. The metal pads 58 typically have a critical dimension, i.e., width, which is great than a critical dimension, i.e., width, of the underlying terminal metal pad structure 56 such that the metal pad 58 lands on surface of the underlying terminal metal pad structure 56 as well as a surface of the second ILD layer 54.

Referring now to FIG. 8C, there is illustrated the exemplary structure of FIG. 8B after forming a first dielectric liner 60 and a second dielectric liner 62. The first dielectric liner 60 is composed of a first dielectric liner material, while the second dielectric liner 62 is composed of a second dielectric liner material that is compositionally different from the first dielectric liner material. In one example, the first dielectric liner material that provides the first dielectric liner 60 is compose of silicon dioxide, and the second dielectric layer material that provides the second dielectric liner 62 is composed of silicon nitride. The first dielectric liner 60 and the second dielectric liner 62 can be formed utilizing a deposition process. In some embodiments a conformal deposition process can be used in providing at least one of the first dielectric liner 60 or the second dielectric liner 62. The conformal deposition process provides a conformal layer having a thickness along a vertical sidewall of a material layer/structure that is substantially the same as a thickness along a horizontal surface of the same material layer/structure. As is illustrated, the first dielectric liner 60 is formed along a topmost surface of the second ILD layer 54 and along a sidewall and a topmost surface of each of the metal pads 58. The second dielectric liner 62 is formed on an entirety of the first dielectric liner 60. Note that the metal pads 58 and the terminal metal pad structures 56 are electrical components in which solder contact resistance measurement can be performed. Note that the electrical components can be symmetrical or asymmetrically spaced apart from one another.

Referring now to FIG. 8D, there is illustrated the exemplary structure of FIG. 8C after forming a patterned dielectric layer 64 having openings therein, and thereafter revealing each underlying metal pad 58 by etching through the second dielectric liner 62 and the first dielectric liner 60. The patterned dielectric layer 64 can be composed of an ILD material as mentioned above or a photoimageable dielectric material such as, for example, a photosensitive polyimide. When an ILD material is used in forming the patterned dielectric layer 64, the patterned dielectric layer 64 can be formed by deposition of the ILD material, followed by lithography and etching to form the openings in the as-deposited ILD material. When a photoimageable dielectric material is used in forming the patterned dielectric layer 64, the photoimageable dielectric material is first deposited and then openings are formed utilizing lithography without a separate etching step. The etch that reveals each underlying metal pad 58 is performed through the openings provided in the patterned dielectric layer 64. The etch physically exposes a topmost surface of each of the underlying metal pads 58 that is shown in FIG. 8D. In FIG. 8D, each opening 68 represents an opening that is formed into the second dielectric liner 62 and the first dielectric liner 60 that reveals an underlying metal pad 58.

Referring now to FIG. 8E, there is illustrated the exemplary structure of FIG. 8D after forming a metal seed layer 68. In some embodiments, and prior to forming metal seed layer 68, a liner such as, for example, Ti liner, can be formed The metal seed layer 68 provides adhesion and acts as a nucleation layer for the subsequent UBM. The metal seed layer 68 can be composed of, for example, Cu, and it can be formed by a deposition process. The metal seed layer 68 is present along a topmost surface and a sidewall surface of the patterned dielectric material layer 64, and is present along a sidewall surface of the second dielectric liner 62 and the first dielectric liner 60 and is further present along a topmost surface of each revealed underlying metal pad 58.

Referring now to FIG. 8F, there is illustrated the exemplary structure of FIG. 8E after forming a patterned masking layer 70. The patterned mask layer 70 is composed of one or more masking materials including for example, an organic planarization layer (OPL). The patterned mask layer 70 can be formed by deposition of the one or more masking materials, followed by photolithographic patterning. The patterned masking layer 70 has an opening that defines an area in which a solder bridge in accordance with the present application can be subsequently formed.

Referring now to FIG. 8G, there is illustrated the exemplary structure of FIG. 8F after forming a solder bridge including a first UBM layer 72, a second UBM layer 74 and solder 76. Note solder bridge shown in FIG. 8G is equivalent to solder bridge 22 shown in FIGS. 1A-7B. The first UBM layer 72 is composed of a first under ball metal, while the second UBM layer 74 is composed of a second under ball metal that is compositionally different from the first under ball metal. In one example, the first under ball metal that provides the first UBM layer 72 is composed of Cu, while the second under ball metal that provides the second UBM layer 74 is composed of Ni. The first UBM layer 72 and the second UBM layer 74 are formed by separate plating processes. The first UBM layer 72 nucleates on, and grows from, the underlying metal seed layer 68 that is revealed by the patterned masking layer 70. The solder 76 that provides an upper component of the solder bridge of the present application can include lead containing solder or lead free solder as mentioned above for solder 20. The solder 76 can be formed by a deposition process.

Referring now to FIG. 8H, there is illustrated the exemplary structure of FIG. 8G after removing the patterned masking layer 70. The patterned masking layer 70 can be removed utilizing a material removal process that is selective in removing the one or more masking materials that provide the patterned masking layer 70. In one example, ashing can be used to remove the patterned masking layer.

Referring now to FIG. 8I, there is illustrated the exemplary structure of FIG. 8H after removing physically exposed portion of the metal seed layer 68 that is not located directly beneath the solder bridge; the remaining metal seed layer 68 that is present beneath the solder bridge is now referred to as metal seed liner 68L. The physically exposed portion of the metal seed layer 68 that is not located directly beneath the solder bridge can be removed.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A structure comprising:
an integrated circuit containing structure comprising a far back-end having a plurality of electrical components located in a test area; and
a solder bridge in electrical contact with each electrical component of the plurality of electrical components present in the test area, wherein the solder bridge is configured to measure solder contact resistance of at least one of the electrical components of the plurality of electrical components present in the test area.

2. The structure of claim 1, wherein each of the electrical components in the test area is symmetrically spaced apart from each other.

3. The structure of claim 1, wherein the electrical components in the test area are asymmetrically spaced apart from each other.

4. The structure of claim 1, wherein the solder bridge comprises under ball metallurgy located beneath a continuous layer of solder.

5. The structure of claim 4, wherein the under ball metallurgy comprises a first under ball metal layer composed of a first under ball metal and a second under ball layer composed of a second under ball metal, wherein the second under ball metal is compositionally different from the first under ball metal.

6. The structure of claim 1, wherein each of the electrical components in the test area comprises metal wiring and a terminal metal pad containing structure.

7. The structure of claim 1, further comprising a first probe, a second probe, a third probe and a fourth probe electrically wired to the electrical components of the plurality of electrical components present in the test area.

8. The structure of claim 7, wherein each of the first probe, the second probe, the third probe and the fourth probe comprises metal wiring.

9. The structure of claim 7, wherein each of the first probe, the second probe, the third probe and the fourth probe comprises metal wiring, a terminal metal pad containing structure, under ball metallurgy and solder.

10. The structure of claim 7, wherein each of the first probe, the second probe, the third probe and the fourth probe contacts a plurality of solder bumps.

11. A structure comprising:
an integrated circuit containing structure comprising a far back-end having a plurality of electrical components located in a test area; and
a solder bridge in electrical contact with each electrical component of the plurality of electrical components present in the test area, wherein the solder bridge is configured to measure solder sheet resistivity of the electrical components of the plurality of electrical components present in the test area.

12. The structure of claim 11, wherein the solder bridge comprises under ball metallurgy located beneath a continuous layer of solder.

13. The structure of claim 12, wherein the under ball metallurgy comprises a first under ball metal layer composed of a first under ball metal and a second under ball layer composed of a second under ball metal, wherein the second under ball metal is compositionally different from the first under ball metal.

14. The structure of claim 11, wherein each of the electrical components in the test area comprises metal wiring.

15. The structure of claim 11, further comprising a plurality of probes electrically wired to the electrical components of the plurality of electrical components present in the test area.

16. A structure comprising:
an integrated circuit containing structure comprising a far back-end having a plurality of electrical components located in a test area; and
an elongated shaped solder bridge in electrical contact with each electrical component of the plurality of electrical components present in the test area, wherein the elongated shaped solder bridge is configured to measure solder contact resistance of at least one of the electrical components of the plurality of electrical components present in the test area.

17. The structure of claim 16, wherein each of the electrical components in the test area is symmetrically spaced apart from each other.

18. The structure of claim 16, wherein the electrical components in the test area are asymmetrically spaced apart from each other.

19. The structure of claim 16 wherein the elongated shaped solder bridge under ball metallurgy located beneath a continuous layer of solder.

20. The structure of claim 16, further comprising a first probe, a second probe, a third probe and a fourth probe electrically wired to the electrical components of the plurality of electrical components present in the test area.
